(19) United States
(12) Patent Application Publication
(10) Pub. No.: US 2026/0020459 A1
(43) Pub. Date: Jan. 15, 2026

(54) DISPLAY APPARATUS AND ELECTRONIC DEVICE INCLUDING THE SAME

(71) Applicant: Samsung Display Co., Ltd., Yongin-si (KR)

(72) Inventors: Keunwoo Kim, Yongin-si (KR); Soyoung Koo, Yongin-si (KR); Hyungjun Kim, Yongin-si (KR); Geunchul Park, Yongin-si (KR); Joonseok Park, Yongin-si (KR); Sunhee Lee, Yongin-si (KR); Hyelim Choi, Yongin-si (KR)

(73) Assignee: Samsung Display Co., Ltd., Yongin-si (KR)

(21) Appl. No.: 19/269,328

(22) Filed: Jul. 15, 2025

(30) Foreign Application Priority Data
Jul. 15, 2024 (KR) 10-2024-0093331

(51) Int. Cl. H10K 59/131; G09G 3/3233

(52) U.S. Cl. CPC H10K 59/131; G09G 3/3233; G09G 2300/0842

(57) ABSTRACT

A display apparatus including a display area and a peripheral area includes a substrate, a first layer disposed on the substrate and including a gate driving circuit including a first transistor, a second layer disposed on the first layer and including a metal layer, and a pixel circuit layer disposed on the second layer and including a plurality of pixel circuits each including a second transistor, wherein, in a plan view, the metal layer and the gate driving circuit overlap each other.

### CROSS-REFERENCE TO RELATED APPLICATION(S)

This application claims priority to and benefits of Korean Patent Application No. 10-2024-0093331 under 35 U.S.C. § 119, filed on Jul. 15, 2024, in the Korean Intellectual Property Office, the entire contents of which are incorporated herein by reference.

### BACKGROUND

### 1. Technical Field

One or more embodiments relate to an apparatus, and more particularly, to an electronic device including a display apparatus.

### 2. Description of the Related Art

Mobility-based electronic devices are widely used. Recently, tablet personal computers (PCs), in addition to small electronic devices such as mobile phones, have been widely used as mobile electronic devices.

A mobile electronic device includes a display apparatus for providing visual information such as an image to a user, in order to support various functions. Recently, as other components for driving a display apparatus have been miniaturized, the proportion of a display apparatus in an electronic device has gradually increased, and a structure that is bendable to a certain angle from a flat state has been developed.

### SUMMARY

One or more embodiments include a display apparatus in which a dead area (or peripheral area) is reduced and the performance of a pixel circuit is improved.

However, the embodiments are examples and embodiments to be achieved by the disclosure are not limited thereto.

Additional aspects will be set forth in part in the description which follows and, in part, will be apparent from the description, or may be learned by practice of the embodiments.

According to one or more embodiments, a display apparatus including a display area and a peripheral area includes a substrate, a first layer disposed on the substrate and including a gate driving circuit including a first transistor, a second layer disposed on the first layer and including a metal layer, and a pixel circuit layer disposed on the second layer and including a plurality of pixel circuits each including a second transistor, wherein, in a plan view, the metal layer and the gate driving circuit overlap each other.

In an embodiment, the display area may include a first display area and a second display area, wherein, in a plan view, each of the metal layer and the gate driving circuit overlaps the first display area, and in a plan view, each of the metal layer and the gate driving circuit may be spaced apart from the second display area.

In an embodiment, the first display area may include a 1-1 display area and a 1-2 display area, wherein the gate driving circuit may be provided in plural and may be disposed in each of the 1-1 display area and the 1-2 display area.

In an embodiment, the second display area may be disposed between the 1-1 display area and the 1-2 display area.

In an embodiment, the display apparatus may further include a first wiring that electrically connects a first semiconductor layer of the first transistor to a second gate electrode of the second transistor.

In an embodiment, the first wiring may pass through the second layer.

In an embodiment, the metal layer may have a substantially constant voltage level.

In an embodiment, the display apparatus may further include a second wiring that electrically connects the metal layer to a driving voltage.

In an embodiment, the display apparatus may further include a first gate line that electrically connects second gate electrodes of the second transistors of the plurality of pixel circuits to each other.

In an embodiment, the first gate line may be disposed on the pixel circuit layer.

According to one or more embodiments, a display apparatus including a display area and a peripheral area includes a substrate, a first layer disposed on the substrate and including a gate driving circuit including a first transistor, a second layer disposed on the first layer and including a metal layer overlapping the gate driving circuit, and a pixel circuit layer disposed on the second layer and including a plurality of pixel circuits each including a second transistor, wherein, in a plan view, at least one of the plurality of pixel circuits may be spaced apart from the gate driving circuit.

In an embodiment, the display area may include a first display area and a second display area, wherein, in a plan view, each of the metal layer and the gate driving circuit overlaps the first display area, and in a plan view, each of the metal layer and the gate driving circuit may be spaced apart from the second display area.

In an embodiment, the first display area may include a 1-1 display area and a 1-2 display area, wherein the gate driving circuit may be provided in plural and may be disposed in each of the 1-1 display area and the 1-2 display area.

In an embodiment, the second display area may be disposed between the 1-1 display area and the 1-2 display area.

In an embodiment, the display apparatus may further include a first wiring that electrically connects a first semiconductor layer of the first transistor to a second gate electrode of the second transistor.

In an embodiment, the first wiring may pass through the second layer.

In an embodiment, the metal layer may have a substantially constant voltage level.

In an embodiment, the display apparatus may further include a second wiring that electrically connects the metal layer to a driving voltage.

In an embodiment, the display apparatus may further include a first gate line that electrically connects second gate electrodes of the second transistors of the plurality of pixel circuits to each other.

In an embodiment, the first gate line may be disposed on the pixel circuit layer.

In an embodiment, an electronic device may include: a display apparatus including a display area and a peripheral area, the display apparatus including: a substrate; a first layer disposed on the substrate and including a gate driving circuit including a first transistor; a second layer disposed on the first layer and including a metal layer; and a pixel circuit layer disposed on the second layer and including a plurality of pixel circuits each including a second transistor, wherein, in a plan view, the metal layer and the gate driving circuit may overlap each other.

The display area may include a first display area and a second display area, wherein, in a plan view, each of the metal layer and the gate driving circuit may overlap the first display area, and in a plan view, each of the metal layer and the gate driving circuit may be spaced apart from the second display area.

The first display area may include a 1-1 display area and a 1-2 display area, and the gate driving circuit may be provided in plural and may be disposed in each of the 1-1 display area and the 1-2 display area.

The second display area may be disposed between the 1-1 display area and the 1-2 display area.

The metal layer may have a substantially constant voltage level.

The electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIGS. 1 and 2 are schematic views of a display apparatus, according to an embodiment;

FIG. 3 is a schematic diagram of a gate driving circuit, according to an embodiment;

FIG. 4 is a schematic diagram of an arbitrary stage constituting a gate driving circuit, according to an embodiment;

FIG. 5 is a schematic diagram of an equivalent circuit of a pixel, according to an embodiment;

FIG. 6 is a schematic diagram of a gate driving circuit, according to an embodiment;

FIG. 7 is a schematic diagram of one stage of the gate driving circuit of FIG. 6;

FIGS. 8 to 10 are schematic cross-sectional views illustrating a display apparatus, according to an embodiment;

FIG. 11 is a schematic plan view illustrating a display apparatus, according to an embodiment; and

FIGS. 12 to 16 are schematic plan views illustrating a display apparatus, according to an embodiment.

FIGS. 17 and 18 are schematic perspective views illustrating application examples of electronic devices.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When a certain embodiment may be implemented differently, a specific process order may be different from the described order. For example, two consecutively described processes may be performed substantially at the same time or may be performed in an order opposite to the described order.

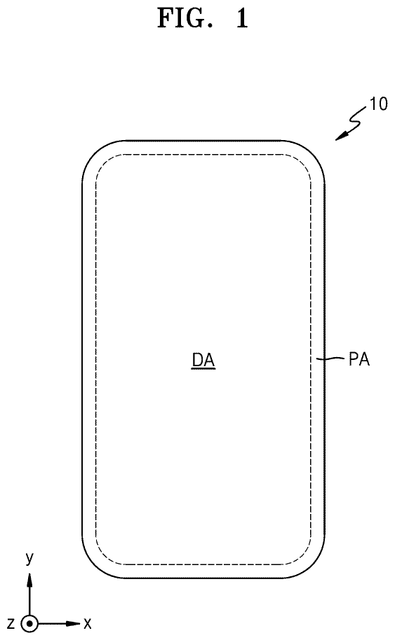

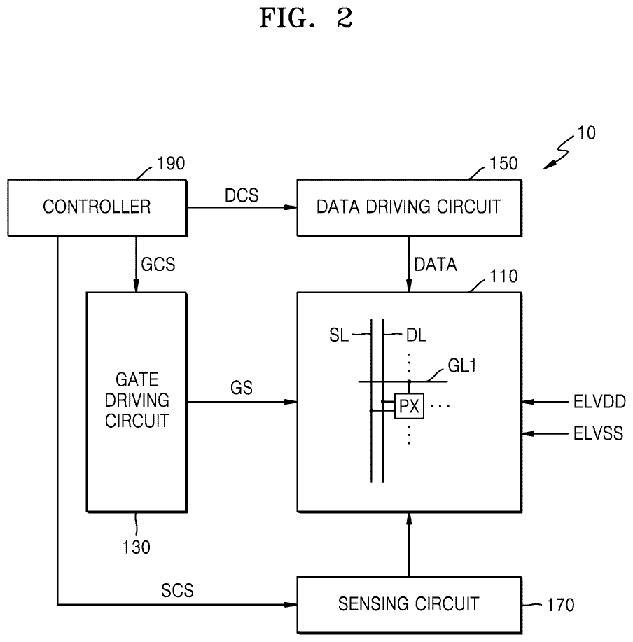

FIGS. 1 and 2 are schematic views of a display apparatus 10, according to an embodiment.

Referring to FIG. 1, the display apparatus 10 may include a display area DA where an image is displayed and a peripheral area PA outside the display area DA. The display apparatus 10 may provide an image through an array of pixels PX (see FIG. 2) that are two-dimensionally arranged in the display area DA. The peripheral area PA where an image is not provided may entirely or partially surround the display area DA. A pad to which an electronic device, a printed circuit board, or the like may be electrically connected may be disposed in the peripheral area PA.

In a plan view, the display area DA may have a rectangular shape. In another embodiment, the display area DA may have a polygonal shape (e.g., a triangular shape, a pentagonal shape, or a hexagonal shape), a circular shape, an elliptical shape, or an irregular shape. The display area DA may have a shape with round corners. In an embodiment, the display apparatus 10 may include the display area DA having a shape in which a length in a y-direction is greater than a length in an x-direction as shown in FIG. 1. In another embodiment, the display apparatus 10 may include the display area DA having a shape in which a length in the x-direction is greater than a length in the y-direction.

Referring to FIGS. 1 and 2, the display apparatus 10 may include a pixel unit 110, a gate driving circuit 130, a data driving circuit 150, a sensing circuit 170, and a controller 190.

The pixel unit 110 may be provided in the display area DA. In the peripheral area PA outside the display area DA, various conductive lines that transmit an electrical signal to be applied to the display area DA, outer driving circuits electrically connected to pixel circuits, and pads to which a printed circuit board or a driver integrated circuit (IC) chip is attached may be disposed. For example, in the peripheral area PA, the data driving circuit 150, the sensing circuit 170, and the controller 190 may be provided.

In the pixel unit 110, first gate lines GL1, data lines DL, sensing lines SL, and pixels PX connected to the first gate lines GL1, the data lines DL, and the sensing lines SL may be disposed. The pixels PX may be arranged in any of various shapes such as a stripe arrangement, a pentile arrangement (diamond arrangement), or a mosaic arrangement, to display an image. Each pixel PX may include an organic light-emitting diode OLED as a display element (or light-emitting element), and the organic light-emitting diode OLED may be connected to a pixel circuit. The pixel circuit may include transistors and at least one capacitor. Each pixel PX may emit light, for example, red light, green light, blue light, or white light, through the organic light-emitting diode OLED. Each pixel PX may be connected to a corresponding first gate line from among the first gate lines GL1, a corresponding sensing line from among the sensing lines SL, and a corresponding data line from among the data lines DL.

In the display area DA, the pixels PX may overlap the gate driving circuit 130. Accordingly, a dead area may be reduced and the display area DA may be expanded.

Each of the first gate lines GL1 may extend in the x-direction (or row direction) and may be connected to the pixels PX arranged in the same row. Each of the first gate lines GL1 may transmit a gate signal to the pixels PX in the same row. Each of the data lines DL may extend in the y-direction (or column direction) and may be connected to the pixels PX arranged in the same column. Each of the data lines DL may transmit a data signal to each of the pixels PX in the same column in synchronization with a gate signal. Each of the sensing lines SL may extend in the y-direction (or column direction) and may be connected to the pixels PX arranged in the same column.

The gate driving circuit 130 may be connected to the first gate lines GL1, may generate a gate signal in response to control signals GCS from the controller 190, and may sequentially supply the gate signals to the first gate lines GL1. The first gate line GL1 may be connected to a gate of a transistor included in the pixel PX. A gate signal may be a gate control signal for controlling to turn on or off a transistor whose gate is connected to the first gate line GL1. A gate signal may be a square wave signal (or pulse signal) including a gate-on voltage for turning on a transistor and a gate-off voltage for turning off the transistor.

The data driving circuit 150 may be connected to the data lines DL and may supply a data signal DATA to the data lines DL in response to a control signal DCS from the controller 190. The data signal DATA supplied to the data line DL may be supplied to the pixel PX to which the gate signal is supplied. The data driving circuit 150 may convert input image data having a gray level input from the controller 190 into the data signal DATA in the form of a voltage or current.

The sensing circuit 170 may be connected to the sensing lines SL and may sense state information of the pixels PX through the sensing lines SL during a sensing period in response to a control signal SCS from the controller 190. In an embodiment, the sensing line SL may be provided for each vertical line (or column). In another embodiment, multiple columns of pixels PX may share a single sensing line SL. The sensing circuit 170 may measure state information of the pixels PX based on current and/or a voltage fed back through the sensing lines SL. The state information may include at least one of a threshold voltage of a driving transistor included in the pixel PX, a mobility, and deterioration information of an organic light-emitting diode that is a display element. The state information of the pixel PX may be transmitted to the controller 190 and/or the data driving circuit 150 and may be used to correct the data signal DATA.

The controller 190 may generate the control signals GCS, DCS, and SCS based on signals input from the outside, and may supply the control signals GCS, DCS, and SCS to the gate driving circuit 130, the data driving circuit 150, and the sensing circuit 170. The control signal GCS output to the gate driving circuit 130 may include clock signals and a start signal. The control signal DCS output to the data driving circuit 150 may include a start signal and clock signals.

The display apparatus 10 may supply a driving voltage ELVDD and a common voltage ELVSS to the pixels PX. The driving voltage ELVDD may be a high-level voltage provided to a first electrode (or pixel electrode or anode) of a display element included in the pixel PX. The common voltage ELVSS may be a low-level voltage provided to a second electrode (or counter electrode or cathode) of the display element included in the pixel PX.

The data driving circuit 150, the sensing circuit 170, and the controller 190 may each be formed as a separate integrated circuit chip or one integrated circuit chip and may be disposed on a flexible printed circuit board (FPCB) electrically connected to a pad disposed on a side of a substrate. In another embodiment, the data driving circuit 150, the sensing circuit 170, and the controller 190 may be disposed (e.g., directly disposed) on the substrate in a chip-on-glass (COG) or chip-on-plastic (COP) manner.

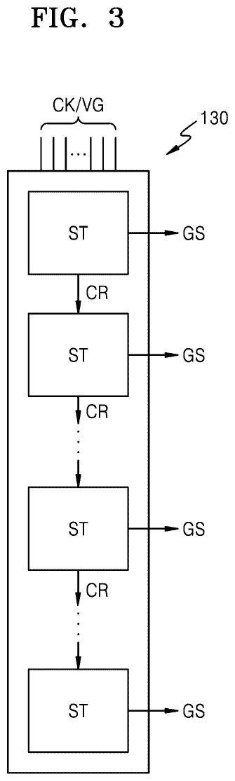

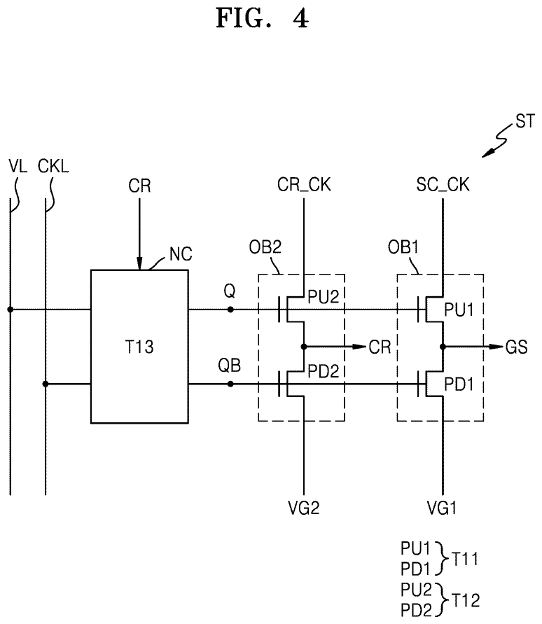

Hereinafter, although an organic light-emitting display apparatus is described as the display apparatus 10 according to an embodiment, the display apparatus of the disclosure is not limited thereto. In another embodiment, the display apparatus of the disclosure may be a display apparatus such as an inorganic light-emitting display apparatus (or an inorganic electroluminescent (EL) display apparatus) or a quantum dot light-emitting display apparatus. FIG. 3 is a schematic diagram of the gate driving circuit 130, according to an embodiment. FIG. 4 is a schematic diagram of an arbitrary stage ST constituting the gate driving circuit 130, according to an embodiment.

The gate driving circuit 130 may include stages ST, and each stage ST may receive at least one clock signal CK and at least one voltage signal VG and may generate at least one gate signal GS (also referred to as a ‘first output signal’). The stage ST may receive at least one clock signal CK from at least one clock line CKL and may receive at least one voltage signal VG from at least one voltage line VL. The stage ST may output at least one gate signal GS to at least one first gate line connected to the stage ST. The stage ST may output a carry signal CR (also referred to as a ‘second output signal’) to a front stage and/or a rear stage.

As shown in FIG. 4, the stage ST may include a control circuit NC, a first output circuit OB1, and a second output circuit OB2.

The control circuit NC may control voltage levels of a first control node Q and a second control node QB. The first control node Q may be set to a first voltage level, and the second control node QB may be set to a second voltage level. In an embodiment, the first voltage level may be a high-level voltage, and the second voltage level may be a low-level voltage.

The control circuit NC may include a 13^{th} transistor T13 and may receive the carry signal CR from a front stage. The control circuit NC may be connected to at least one voltage line VL and at least one clock line CKL. The first output circuit OB1 may output a gate signal GS, and the second output circuit OB2 may output a carry signal CR.

The first output circuit OB1 may include an 11^{th} transistor T11 connected between a terminal to which a scan clock signal SC_CK is input and a terminal to which a voltage VG1 of a second level voltage is input. The 11^{th} transistor T11 may include a pull-up transistor PU1 and a pull-down transistor PD1. The second output circuit OB2 may include a 12^{th} transistor T12 connected between a terminal to which a carry clock signal CR_CK is input and a terminal to which a voltage VG2 of a second level voltage is input. The 12^{th} transistor T12 may include a pull-up transistor PU2 and a pull-down transistor PD2. The pull-up transistors PU1 and PU2 may be turned on or off according to a voltage level of the first control node Q, and the pull-down transistors PD1 and PD2 may be turned on or off according to a voltage level of the second control node QB.

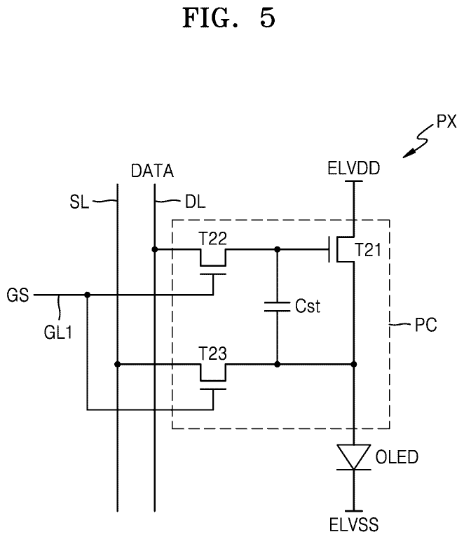

FIG. 5 is a schematic diagram of an equivalent circuit of the pixel PX, according to an embodiment.

Referring to FIG. 5, each of the pixels PX may include a pixel circuit PC and an organic light-emitting diode OLED as a display element connected to the pixel circuit PC. The pixel circuit PC may include a 21^{st} transistor T21, a 22^{nd} transistor T22, a 23^{rd} transistor T23, and a storage capacitor Cst. The 21^{st} transistor T21 may be a driving transistor that outputs driving current corresponding to a data signal, and the 22^{nd} and 23^{rd} transistors T22 and T23 may be switching transistors that transmit signals. A first terminal (or first electrode) and a second terminal (or second electrode) of each of the 21^{st} to 23^{rd} transistors T21 to T23 may be a source or a drain according to voltages of the first terminal and the second terminal. For example, according to voltages of the first terminal and the second terminal, the first terminal may be a drain and the second terminal may be a source, or the first terminal may be a source and the second terminal may be a drain.

The 21^{st} transistor T21 may include the first terminal connected to a first power supply for supplying a driving voltage ELVDD and the second terminal connected to a first electrode (or pixel electrode) of the organic light-emitting diode OLED. The 21^{st} transistor T21 may control driving current flowing from the first power supply to the organic light-emitting diode OLED in response to a voltage stored in the storage capacitor Cst. The organic light-emitting diode OLED may emit light with a certain luminance due to the driving current.

The 22^{nd} transistor T22 (or write transistor) may include a gate connected to a first gate line GL1, the first terminal connected to the data line DL, and the second terminal connected to a gate of the 21^{st} transistor T21. The 22^{nd} transistor T22 may be turned on by a gate signal GS supplied through the first gate line GL1 to electrically connect the data line DL to the gate of the 21^{st} transistor T21 and transmit a data signal DATA input through the data line DL to the gate of the 21^{st} transistor T21.

The 23^{rd} transistor T23 (or sensing transistor) may include a gate connected to the first gate line GL1, the first terminal connected to the second terminal of the 21^{st} transistor T21 and the first electrode of the organic light-emitting diode OLED, and the second terminal connected to the sensing line SL. The 23^{rd} transistor T23 may be turned on by the gate signal GS supplied through the first gate line GL1 to electrically connect the sensing line SL to the first electrode of the organic light-emitting diode OLED and transmit a sensing signal supplied through the sensing line SL to the first electrode of the organic light-emitting diode OLED.

The storage capacitor Cst may be connected between the gate of the 21^{st} transistor T21 and the second terminal of the first transistor T1. The storage capacitor Cst may store a voltage corresponding to a difference between a voltage received from the 22^{nd} transistor T22 and a voltage of the second terminal of the 21^{st} transistor T21.

The organic light-emitting diode OLED may include the first electrode (or pixel electrode) connected to the second terminal of the 21^{st} transistor T21 and a second electrode (or counter electrode) connected to a second power supply to which a common voltage ELVSS is applied. The organic light-emitting diode OLED may emit light with a luminance corresponding to the amount of driving current supplied from the 21^{st} transistor T21.

Although the transistors of the pixel circuit PC are N-type transistors in FIG. 5, embodiments are not limited thereto. For example, the transistors of the pixel circuit PC may be P-type transistors, or some may be P-type transistors and others may be N-type transistors, according to various embodiments.

According to an embodiment, at least the 21^{st} transistor T21 may be an oxide thin-film transistor including a semiconductor layer formed of an amorphous or crystalline oxide semiconductor. For example, the 21^{st} to 23^{rd} transistors T21 through T23 may be oxide thin-film transistors. The oxide thin-film transistors may have excellent off-current characteristics. The oxide semiconductor may include a Zn oxide-based material such as Zn oxide, In—Zn oxide, or Ga—In—Zn oxide. In some embodiments, the oxide semiconductor may be an In—Ga—Zn—O (IGZO) semiconductor. In some embodiments, the oxide semiconductor may be an In—Sn—Ga—Zn—O (ITGZO) semiconductor. In an embodiment, the oxide thin-film transistor may be a low-temperature polycrystalline oxide (LTPO) thin-film transistor. In another example, at least one of the 21^{st} to 23^{rd} transistors T21 to T23 may be a low-temperature poly-silicon (LTPS) thin-film transistor including an active layer formed of polysilicon.

In case that a gate signal is supplied through a corresponding first gate line during a driving period, the pixel PX may receive a data signal from a corresponding data line. The pixel PX receiving the data signal may control the amount of current flowing from the driving voltage ELVDD to the common voltage ELVSS via the organic light-emitting diode OLED in response to the data signal. For example, the organic light-emitting diode OLED may generate light with a certain luminance in response to the amount of current.

In case that a sensing signal is supplied through a corresponding first gate line during a sensing period, the pixel PX may output current and/or a voltage to the sensing line based on the sensing signal supplied to a corresponding data line.

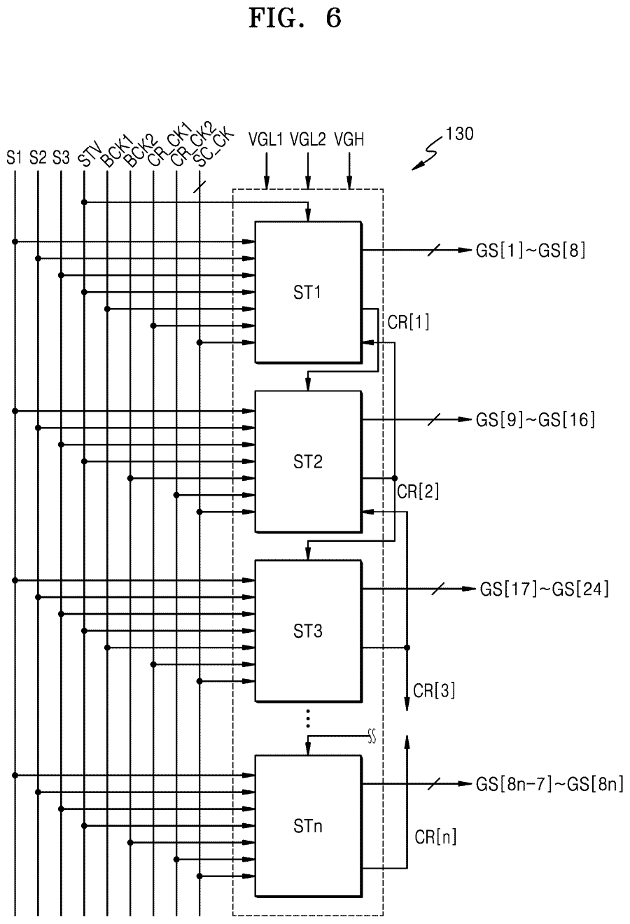

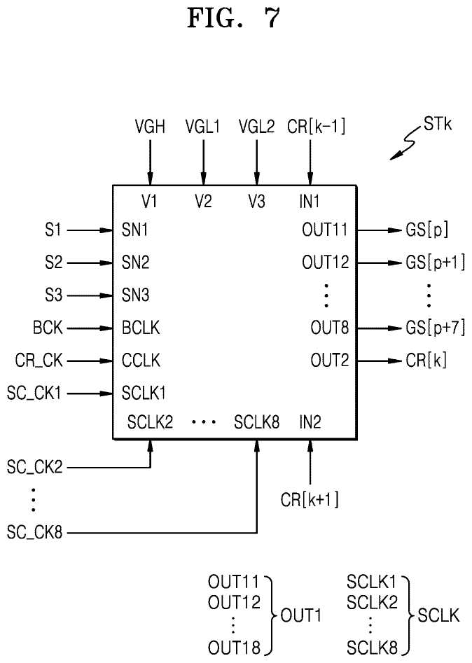

FIG. 6 is a schematic diagram of the gate driving circuit 130, according to an embodiment. FIG. 7 is a schematic diagram of a stage ST of the gate driving circuit 130 of FIG. 6.

The gate driving circuit 130 according to an embodiment may include stages (e.g., ST1 to STn). The stages (e.g., ST1 to STn) may sequentially output gate signals (or first output signals) (e.g., GS[1] to GS[8n]) to first gate lines. The number of stages provided in the gate driving circuit 130 may vary according to the number of rows (or horizontal lines) provided in the pixel unit 110.

Each of the stages (e.g., ST1 to STn) of the gate driving circuit 130 according to an embodiment may generate two or more gate signals corresponding to two or more rows and may output the two or more gate signals to corresponding two or more first gate lines. In an embodiment, as shown in FIG. 6, each of the stages (e.g., ST1 to STn) may generate eight gate signals and may sequentially output the eight gate signals to eight first gate lines of corresponding eight rows. For example, the number of stages may be ⅛ of the number of rows (or horizontal lines) provided in the pixel unit 110. For example, a first stage ST1 may sequentially output a first gate signal GS[1] to an eighth gate signal GS[8] to first to eighth first gate lines. An n^{th} stage STn may output an 8n-7^{th} gate signal GS[8n-7] to an 8n^{th} gate signal GS[8n] to 8n-3^{th} to 8n^{th} first gate lines.

Referring to FIGS. 6 and 7, each of the stages (e.g., ST1 to STn) of the gate driving circuit 130 may include a first input terminal IN1, a second input terminal IN2, a first voltage input terminal V1, a second voltage input terminal V2, a third voltage input terminal V3, a first clock terminal BCLK, a second clock terminal CCLK, a third clock terminal SCLK, a first control signal terminal SN1, a second control signal terminal SN2, a third control signal terminal SN3, a first output terminal OUT1, and a second output terminal OUT2.

First output terminals OUT1 may be provided to output gate signals. For example, each stage may include eight first output terminals (e.g., OUT11 to OUT18) to output eight gate signals. Third clock terminals SCLK may be provided corresponding to the first output terminals. For example, the third clock terminal SCLK of each stage may include eight third clock terminals SCLK1 to SCLK8.

Each of the stages (e.g., ST1 to STn) may generate a carry signal (or a second output signal) and may supply the carry signal to the first input terminal IN1 of a rear stage and the second input terminal IN2 of a front stage.

A start signal STV or a carry signal output from the front stage (hereinafter, referred to as a ‘previous carry signal’) may be input to the first input terminal IN1. For example, the start signal STV may be input to the first input terminal IN1 of the first stage ST1, and the previous carry signal may be input as a start signal to the first input terminal IN1 of each of second to n^{th} stages ST2 to STn. The front stage may be at least one previous stage. In FIGS. 6 and 7, the front stage may be a stage immediately before a current stage. For example, as shown in FIG. 7, a carry signal CR[k−1] output from a k−1^{th} stage may be input as a start signal to the first input terminal IN1 of a kth stage STK.

A carry signal output from the rear stage (hereinafter, referred to as a ‘next carry signal’) may be input to the second input terminal IN2. The rear stage may be at least one next stage. In FIGS. 6 and 7, the rear stage may be a stage immediately after the current stage. For example, as shown in FIG. 7, a carry signal CR[k+1] output from a k+1^{th} stage may be input to the second input terminal IN2 of the kth stage STk.

A first voltage VGH may be input to the first voltage input terminal V1, a second voltage VGL1 may be input to the second voltage input terminal V2, and a third voltage VGL2 may be input to the third voltage input terminal V3. The second voltage VGL1 may have a lower voltage level than the first voltage VGH. The third voltage VGL2 may have a lower voltage level than the second voltage VGL1. The first voltage VGH, the second voltage VGL1, and the third voltage VGL2 may be input as global signals from the controller 190 of FIG. 1 or a power supply circuit.

A boosting clock signal BCK may be input to the first clock terminal BCLK. The boosting clock signal BCK may include a first boosting clock signal BCK1 and the second boosting clock signal BCK2. The first boosting clock signal BCK1 or the second boosting clock signal BCK2 may be input to the first clock terminal BCLK. The first boosting clock signal BCK1 and the second boosting clock signal BCK2 may be alternately input to the first clock terminals BCLK of the first to n^{th} stages ST1 to STn. For example, the first boosting clock signal BCK1 may be Input to the first clock terminals BCLK of odd-numbered stages ST1, ST3, . . . . The second boosting clock signal BCK2 may be input to the first clock terminals BCLK of even-numbered stages ST2, ST4, . . . .

The first boosting clock signal BCK1 and the second boosting clock signal BCK2 may be square wave signals in which a high-level voltage and a low-level voltage repeat. The high-level voltage may be a gate-on voltage for turning on an N-type transistor, and the low-level voltage may be a gate-off voltage for turning off an N-type transistor. The first boosting clock signal BCK1 and the second boosting clock signal BCK2 may have the same waveform and may be phase-shifted. For example, the second boosting clock signal BCK2 may have the same waveform as the first boosting clock signal BCK1 and may be input with its phase shifted (or delayed) at certain intervals. The second boosting clock signal BCK2 may be half-cycle shifted from the first boosting clock signal BCK1. The first boosting clock signal BCK1 and the second boosting clock signal BCK2 may be set so that a gate-on voltage period may be longer than a gate-off voltage period in one cycle. However, embodiments are not limited thereto, and the first boosting clock signal BCK1 and the second boosting clock signal BCK2 may be set so that a gate-on voltage period may be equal to or shorter than a gate-off voltage period in one cycle. A gate-on voltage and a gate-off voltage of the first boosting clock signal BCK1 and the second boosting clock signal BCK2 may be about 12 V and about-9 V, respectively, but embodiments are not limited thereto.

A carry clock signal CR_CK may be input to the second clock terminal CCLK. The carry clock signal CR_CK may include a first carry clock signal CR_CK1 and a second carry clock signal CR_CK2. The first carry clock signal CR_CK1 or the second carry clock signal CR_CK2 may be input to the second clock terminal CCLK. The first carry clock signal CR_CK1 and the second carry clock signal CR_CK2 may be alternately input to the second clock terminals CCLK of the stages (e.g., ST1 to STn). For example, the first carry clock signal CR_CK1 may be input to the second clock terminals CCLK of the odd-numbered stages ST1, ST3, . . . . The second carry clock signal CR_CK2 may be input to the second clock terminals CCLK of the even-numbered stages ST2, ST4, . . . .

The first carry clock signal CR_CK1 and the second carry clock signal CR_CK2 may be square wave signals in which a high-level voltage and a low-level voltage repeat. The first carry clock signal CR_CK1 and the second carry clock signal CR_CK2 may have the same waveform and may be phase-shifted. For example, the second carry clock signal CR_CK2 may have the same waveform as the first carry clock signal CR_CK1 and may be input with its phase shifted (or delayed) at certain intervals. The first carry clock signal CR_CK1 may be half-cycle shifted from the second carry clock signal CR_CK2. The first carry clock signal CR_CK1 and the second carry clock signal CR_CK2 may be set so that a gate-on voltage period may be shorter than a gate-off voltage period in one cycle. However, embodiments are not limited thereto, and the first carry clock signal CR_CK1 and the second carry clock signal CR_CK2 may be set so that a gate-on voltage period may be equal to or longer than a gate-off voltage period in one cycle. A gate-on voltage and a gate-off voltage of the first carry clock signal CR_CK1 and the second carry clock signal CR_CK2 may be about 12 V and about-9 V, respectively, but embodiments are not limited thereto.

Each of the stages (e.g., ST1 to STn) may include third clock terminals SCLK. One of scan clock signals SC_CK may be input to each of the third clock terminals SCLK. Each of the stages (e.g., ST1 to STn) may include i^{th} third clock terminals SCLK, and may receive i^{th} scan clock signals SC_CK from among 2i^{th} scan clock signals SC_CK. Here, i may be an integer equal to or greater than 2.

In an embodiment, each stage may include eight third clock terminals SCLK1 to SCLK8, and one of eight scan clock signals from among 16 scan clock signals (e.g., first to 16^{th} scan clock signals SC_CK1 to SC_CK16) may be input to each of the third clock terminals SCLK1 to SCLK8. For example, first to eighth scan clock signals SC_CK1 to SC_CK8 may be sequentially input to the third clock terminals SCLK1 to SCLK8 of the odd-numbered stages ST1, ST3, . . . . The ninth to 16^{th} scan clock signals SC_CK9 to SC_CK16 may be sequentially input to the third clock terminals SCLK1 to SCLK8 of the even-numbered stages ST2, ST4, . . . .

The first to 16^{th} scan clock signals SC_CK1 to SC_CK16 may be square wave signals in which a high-level voltage and a low-level voltage repeat. The first to 16^{th} scan clock signals SC_CK1 to SC_CK16 may have the same waveform and may be phase-shifted. The first to 16^{th} scan clock signals SC_CK1 to SC_CK16 may be sequentially phase-shifted so that gate-on voltage periods may partially overlap and may be supplied to the gate driving circuit 130. The first to 16^{th} scan clock signals SC_CK1 to SC_CK16 may be set so that a gate-on voltage period may be shorter than a gate-off voltage period in one cycle. However, embodiments are not limited thereto, and the first to 16^{th} scan clock signals SC_CK1 to SC_CK16 may be set so that a gate-on voltage period may be equal to or longer than a gate-off voltage period in one cycle. A gate-on voltage and a gate-off voltage of the first to 16^{th} scan clock signals SC_CK1 to SC_CK16 may be about 12 V and about-5 V, respectively, but embodiments are not limited thereto.

A first control signal S1 may be input to the first control signal terminal SN1. The first control signal S1 may be selectively supplied as a gate-on voltage to at least one stage corresponding to rows where sensing is to be performed in a corresponding frame so that a sensing node in the stage may be charged.

A second control signal S2 may be input to the second control signal terminal SN2. The second control signal S2 of a gate-on voltage may be supplied so that a voltage of the sensing node charged by the first control signal S1 may be supplied to a first control node in the stage.

A third control signal S3 may be input to the third control signal terminal SN3. The third control signal S3 may be supplied to initialize (or reset) voltages of the first control node and a second control node in case that an operation error of the display apparatus occurs. The third control signal S3 of a gate-on voltage may be supplied for a certain period of time so that the first control node in the stage may be set to a second level voltage and the second control node may be set to a first level voltage.

A gate signal may be output from the first output terminal OUT1. Each of the stages (e.g., ST1 to STn) may include first output terminals OUT1 and may sequentially shift and output gate signals by a certain period of time. Each gate signal may be supplied to a pixel through a corresponding first gate line.

The number of first output terminals OUT1 may be the same as the number of scan clock signals SC_CK input to each stage. For example, eight scan clock signals SC_CK may be input to each of the stages (e.g., ST1 to STn), and each stage may include eight output terminals (e.g., 1-1 to 1-8 output terminals OUT11, OUT12, . . . , and OUT18). As shown in FIG. 7, a p^{th} gate signal GS[p] may be output from the 1-1 output terminal OUT11 of the kth stage STk to a p^{th} first gate line, a p+1^{th} gate signal GS[p+1] may be output from the 1-2 output terminal OUT12 to a p+1^{th} first gate line, and a p+7^{th} gate signal GS[p+7] may be output from the 1-8 output terminal OUT18 to a p+7^{th} first gate line. Here, p may be a positive integer, and p+7 may be 8 k.

A carry signal may be output from the second output terminal OUT2. Carry signals CR[1], CR[2], CR[3], . . . , and CR[n] output from the second output terminals OUT2 of the stages (e.g., ST1 to STn) may be sequentially shifted by a certain period of time. The carry signal may be supplied to the first input terminal IN1 of the rear stage and the second input terminal IN2 of the front stage.

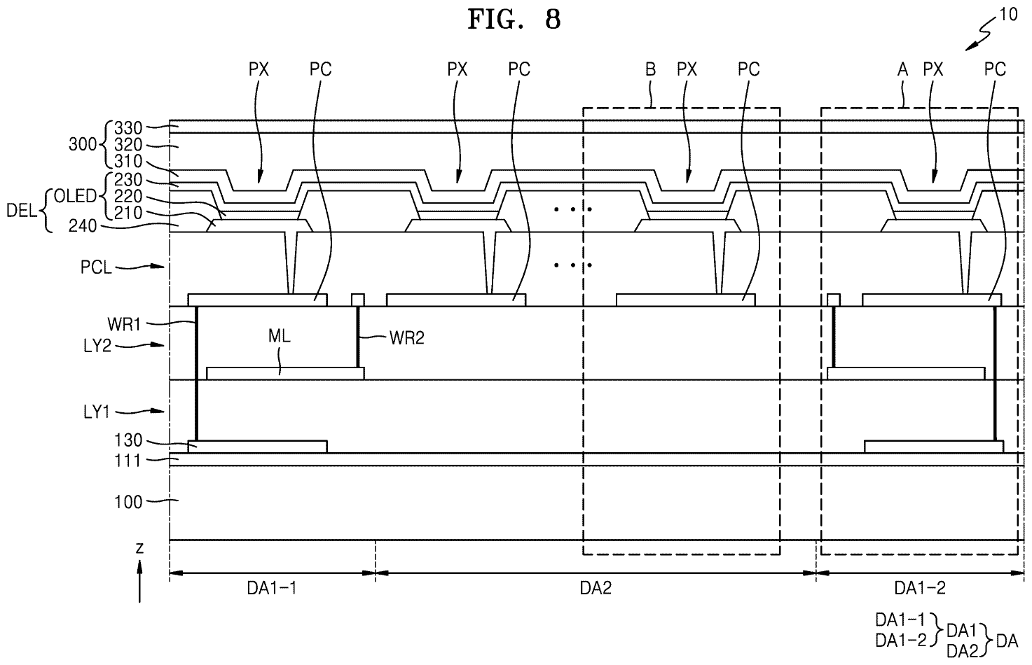

FIGS. 8 to 10 are schematic cross-sectional views of the display apparatus 10, according to an embodiment.

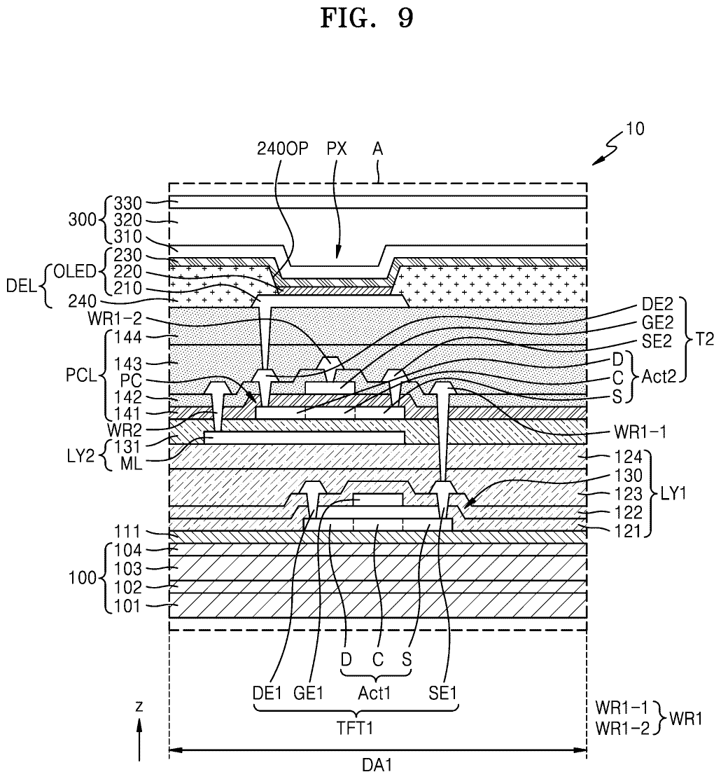

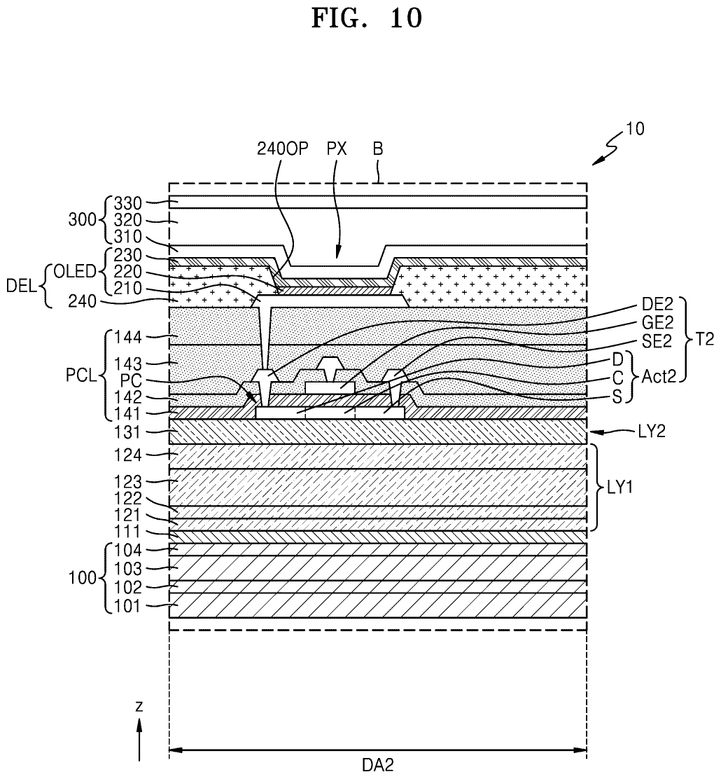

FIGS. 8 to 10 illustrate the display area DA of the display apparatus 10 of FIG. 1. FIG. 8 is a cross-sectional view illustrating a display apparatus taken along a direction perpendicular to a substrate 100. FIG. 9 is an enlarged view corresponding to a portion A of FIG. 8. FIG. 10 is an enlarged view corresponding to a portion B of FIG. 8.

Referring to FIGS. 8 to 10, the display apparatus 10 may include the substrate 100, a first buffer layer 111, a first layer LY1, a second layer LY2, a pixel circuit layer PCL, a display element layer DEL, and an encapsulation layer 300.

The substrate 100 may have a multi-layer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104 which are sequentially stacked. Each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), and/or cellulose acetate propionate (CAP). Each of the first barrier layer 102 and the second barrier layer 104 may include an inorganic insulating material such as silicon oxide, silicon oxynitride, and/or silicon nitride. The substrate 100 may be flexible.

The first buffer layer 111 may be disposed on the substrate 100. The first buffer layer 111 may reduce or block penetration of a foreign material, moisture, or external air from the bottom of the substrate 100 and may planarize the substrate 100. The first buffer layer 111 may include an inorganic insulating material such as silicon oxide, silicon oxynitride, or silicon nitride, and may have a single layer structure or a multi-layer structure including the above material.

The first layer LY1 may be disposed on the first buffer layer 111. For example, the first layer LY1 may be disposed on the substrate 100. The first layer LY1 may include a 1-1 gate insulating layer 121, a 1-2 gate insulating layer 122, a first interlayer insulating layer 123, a first planarization insulating layer 124, and the gate driving circuit 130. The 1-2 gate insulating layer 122 may be disposed on the 1-1 gate insulating layer 121, the first interlayer insulating layer 123 may be disposed on the 1-2 gate insulating layer 122, and the first planarization insulating layer 124 may be disposed on the first interlayer insulating layer 123.

The gate driving circuit 130 may include a first transistor T1. The first transistor T1 may correspond to the 11^{th} transistor T11 described with reference to FIG. 4. For example, the first transistor T1 may be any one of the pull-up transistor PU1 and the pull-down transistor PD1 of the 11^{th} transistor T11 described with reference to FIG. 4. The first transistor T1 may include a first semiconductor layer Act1, a first gate electrode GE1, a first drain electrode DE1, and a first source electrode SE1.

The first semiconductor layer Act1 may include polysilicon. In another example, the first semiconductor layer Act1 may include amorphous silicon, an oxide semiconductor, or an organic semiconductor. The first semiconductor layer Act1 may include a channel region C and a drain region D and a source region S disposed on both sides of the channel region C. The first gate electrode GE1 may overlap the channel region C.

The first gate electrode GE1 may include a low-resistance metal material. The first gate electrode GE1 may include a conductive material including molybdenum (Mo), aluminum (Al), copper (Cu), or titanium (Ti), and may have a single layer structure or a multi-layer structure including the above material.

The 1-1 gate insulating layer 121 between the first semiconductor layer Act1 and the first gate electrode GE1 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The 1-2 gate insulating layer 122 may be disposed to cover the first gate electrode GE1. The 1-2 gate insulating layer 122 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}), like the 1-1 gate insulating layer 121. Zinc oxide (ZnO_{X}) may be zinc oxide (ZnO) and/or zinc peroxide (ZnO₂).

The first interlayer insulating layer 123 may cover the 1-2 gate insulating layer 122. The first interlayer insulating layer 123 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂). The first interlayer insulating layer 123 may have a single layer structure or a multi-layer structure including the above inorganic insulating material.

As shown in FIG. 9, each of the first drain electrode DE1 and the first source electrode SE1 may be disposed on the 1-2 gate insulating layer 122. In another example, unlike in FIG. 9, each of the first drain electrode DE1 and the first source electrode SE1 may be disposed on the first interlayer insulating layer 123. The first drain electrode DE1 and the first source electrode SE may be respectively connected to the drain region D and the source region S through contact holes formed in insulating layers under the first drain electrode DE1 and the first source electrode SE1. Each of the first drain electrode DE1 and the first source electrode SE1 may include a material having excellent conductivity. Each of the first drain electrode DE1 and the first source electrode SE1 may include a conductive material including molybdenum (Mo), aluminum (Al), copper (Cu), or titanium (Ti), and may have a single layer structure or a multi-layer structure including the above material. In an embodiment, each of the first drain electrode DE1 and the first source electrode SE1 may have a multi-layer structure including Ti/Al/Ti.

The first planarization insulating layer 124 may cover the first interlayer insulating layer 123. The first planarization insulating layer 124 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The second layer LY2 may be disposed on the first layer LY1. The second layer LY2 may include a second buffer layer 131 and a metal layer ML.

The second buffer layer 131 may reduce or block penetration of a foreign material, moisture, or external air from the bottom of the first layer LY1 and the substrate 100 and may planarize the substrate 100. The second buffer layer 131 may include an inorganic insulating material such as silicon oxide, silicon oxynitride, or silicon nitride, and may have a single layer structure or a multi-layer structure including the above material.

The metal layer ML may be disposed on the first layer LY1. The second buffer layer 131 may cover the metal layer ML. The metal layer ML may include at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, the metal layer ML may have a single-layer structure including molybdenum, may have a two-layer structure in which a molybdenum layer and a titanium layer are stacked, or may have a three-layer structure in which a titanium layer, an aluminum layer, and a titanium layer are stacked.

The pixel circuit layer PCL may be disposed on the second layer LY2. The pixel circuit layer PCL may include a 2-1 gate insulating layer 141, a 2-2 gate insulating layer 142, a second interlayer insulating layer 143, a second planarization insulating layer 144, and pixel circuits PC. The 2-2 gate insulating layer 142 may be disposed on the 2-1 gate insulating layer 141, the second interlayer insulating layer 143 may be disposed on the 2-2 gate insulating layer 142, and the second planarization insulating layer 144 may be disposed on the second interlayer insulating layer 143.

The pixel circuits PC may include the second transistor T2. The second transistor T2 may correspond to the 21^{st} transistor T21 described with reference to FIG. 5. The second transistor T2 may include a second semiconductor layer Act2, a second gate electrode GE2, a second drain electrode DE2, and a second source electrode SE2.

The second semiconductor layer Act2 may include polysilicon. In another example, the second semiconductor layer Act2 may include amorphous silicon, an oxide semiconductor, or an organic semiconductor. The second semiconductor layer Act2 may include a channel region C and a drain region D and a source region S disposed on both sides of the channel region C. The second gate electrode GE2 may overlap the channel region C.

The second gate electrode GE2 may include a low-resistance metal material. The second gate electrode GE2 may include a conductive material including molybdenum (Mo), aluminum (Al), copper (Cu), or titanium (Ti), and may have a single layer structure or a multi-layer structure including the above material.

The 2-1 gate insulating layer 141 between the second semiconductor layer Act2 and the second gate electrode GE2 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The 2-2 gate insulating layer 142 may be disposed to cover the second gate electrode GE2. The 2-2 gate insulating layer 142 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}), like the 2-1 gate insulating layer 141. Zinc oxide (ZnO_{X}) may be zinc oxide (ZnO) and/or zinc peroxide (ZnO₂).

The second interlayer insulating layer 143 may cover the 2-2 gate insulating layer 142. The second interlayer insulating layer 143 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂). The second interlayer insulating layer 143 may have a single layer structure or a multi-layer structure including the inorganic insulating material.

As shown in FIG. 9, each of the second drain electrode DE2 and the second source electrode SE2 may be disposed on the 2-2 gate insulating layer 142. In another example, unlike in FIG. 9, each of the second drain electrode DE2 and the second source electrode SE2 may be disposed on the second interlayer insulating layer 143. The second drain electrode DE2 and the second source electrode SE2 may be respectively connected to the drain region D and the source region S through contact holes formed in insulating layers under the second drain electrode DE2 and the second source electrode SE2. Each of the second drain electrode DE2 and the second source electrode SE2 may include a material having excellent conductivity. Each of the second drain electrode DE2 and the second source electrode SE2 may include a conductive material including molybdenum (Mo), aluminum (Al), copper (Cu), or titanium (Ti), and may have a single layer structure or a multi-layer structure including the above material. In an embodiment, each of the second drain electrode DE2 and the second source electrode SE2 may have a multi-layer structure including Ti/Al/Ti.

The second planarization insulating layer 144 may cover the second interlayer insulating layer 143. The second planarization insulating layer 144 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The display area DA may include a first display area DA1 and a second display area DA2. At least one of the first display area DA1 and the second display area DA2 may be provided in plural. For example, as shown in FIG. 8, two first display areas DA1 may be provided. For example, the first display area DA1 may include a 1-1 display area DA1-1 and a 1-2 display area DA1-2. For example, in a cross-sectional view (taken along a direction perpendicular to the substrate), the second display area DA2 may be disposed between the 1-1 display area DA1-1 and the 1-2 display area DA1-2. For example, in a cross-sectional view, along a direction, the 1-1 display area DA1-1, the second display area DA2, and the 1-2 display area DA1-2 may be sequentially arranged.

However, this is only an example, and the number and arrangement of the first display areas DA1 and the second display areas DA2 are not limited thereto. Unlike in FIG. 8, one first display area DA1 and one second display area DA2 may be provided.

The pixel circuit PC may be disposed in the display area DA. For example, pixel circuits PC may be disposed in each of the first display area DA1 and the second display area DA2. Accordingly, pixels PX may be disposed in each of the first display area DA1 and the second display area DA2.

The first display area DA1 may be an area where the gate driving circuit 130 is disposed. In a plan view, the gate driving circuit 130 may overlap the first display area DA1. In case that the first display area DA1 includes the 1-1 display area DA1-1 and the 1-2 display area DA1-2, the gate driving circuit 130 may be disposed in each of the 1-1 display area DA1-1 and the 1-2 display area DA1-2.

The second display area DA2 may be an area where the gate driving circuit 130 is not disposed. In a plan view, the gate driving circuit 130 may not overlap the second display area DA2. For example, in a plan view, the gate driving circuit 130 may be spaced apart from the second display area DA2.

A first wiring WR1 may electrically connect the gate driving circuit 130 to the pixel circuit PC. For example, the first wiring WR1 may electrically connect the first semiconductor layer Act1 of the first transistor T1 of the gate driving circuit 130 to the second gate electrode GE2 of the second transistor T2 of the pixel circuit PC. The first wiring WR1 may pass through the second layer LY2. For example, the first wiring WR1 may include a 1-1 wiring WR1-1 and a 1-2 wiring WR1-2.

The 1-1 wiring WR1-1 may pass through at least parts of the pixel circuit layer PCL, the second layer LY2, and the first layer LY1 to be electrically connected to the first semiconductor layer Act1 of the first transistor T1. For example, the 1-1 wiring WR1-1 may pass through the 2-1 gate insulating layer 141, the 2-2 gate insulating layer 142, the second buffer layer 131, the first planarization insulating layer 124, and the first interlayer insulating layer 123 to be electrically connected to the first source electrode SE1 (or the first drain electrode DE1).

Although not shown in FIG. 9, the 1-2 wiring WR1-2 may electrically connect the 1-1 wiring WR1-1 to the second gate electrode GE2 of the second transistor T2. For example, the 1-2 wiring WR1-2 may pass through at least a part of the 2-2 gate insulating layer 142 to be electrically connected to the second gate electrode GE2.

The metal layer ML may be disposed in the first display area DA1. In case that the first display area DA1 includes the 1-1 display area DA1-1 and the 1-2 display area DA1-2, the metal layer ML may be disposed in each of the 1-1 display area DA1-1 and the 1-2 display area DA1-2. The metal layer ML may be disposed between the first transistor T1 and the second transistor T2. In a plan view (viewed in a direction perpendicular to the substrate 100), the metal layer ML may overlap each of the first transistor T1 and the second transistor T2. Accordingly, the metal layer ML may reduce the unintended electrical influence of the first transistor T1 on the second transistor T2.

The metal layer ML may have a substantially constant voltage level. For example, the metal layer ML may be electrically connected to the driving voltage ELVDD described with reference to FIG. 5 through a second wiring WR2, and have the same level as the driving voltage ELVDD. However, this is only an example, and the metal layer ML may be electrically connected to the common voltage ELVSS described with reference to FIG. 5 through the second wiring WR2, and have the same level as the common voltage ELVSS.

The second wiring WR2 may pass through at least parts of the pixel circuit layer PCL and the second layer LY2 to electrically connect the metal layer ML and a substantially constant voltage. For example, the second wiring WR2 may pass through at least parts of the 2-2 gate insulating layer 142, the 2-1 gate insulating layer 141, and the second buffer layer 131.

The metal layer ML may prevent (−) charges from gathering under the second semiconductor layer Act2 of the second transistor T2, thereby preventing or minimizing the occurrence of afterimages caused by the (−) charges. In a plan view, the metal layer ML may overlap (e.g., entirely overlap) the channel region C of the second semiconductor layer Act2 of the second transistor T2.

The display element layer DEL may be disposed on the pixel circuit layer PCL. The display element layer DEL may include an organic light-emitting diode OLED and a bank layer 240. The display element layer DEL may include the organic light-emitting diode OLED as a display element (i.e., a light-emitting element), and the organic light-emitting diode OLED may have a structure in which a pixel electrode 210, an intermediate layer 220, and a common electrode 230 are stacked. The organic light-emitting diode OLED may emit, for example, red light, green light, or blue light, or may emit red light, green light, blue light, or white light. The organic light-emitting diode OLED may emit light through an emission area, and the emission area may be defined as the pixel PX.

The pixel electrode 210 of the organic light-emitting diode OLED may pass through at least a part of the pixel circuit layer PCL to be electrically connected to the pixel circuit PC. For example, the pixel electrode 210 may pass through the second interlayer insulating layer 143 and the second planarization insulating layer 144 to be electrically connected to the second transistor T2.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a film formed of ITO, IZO, ZnO, or In₂O₃ over/under the reflective film.

The bank layer 240 having a pixel opening 240OP, through which a central portion of the pixel electrode 210 is exposed, may be disposed on the pixel electrode 210. The bank layer 240 may include an organic insulating material and/or an inorganic insulating material. The pixel opening 240OP may define the emission area of light emitted by the organic light-emitting diode OLED. For example, a size/width of the pixel opening 240OP may correspond to a size/width of the emission area. Accordingly, a size and/or a width of the pixel PX may depend on a size and/or a width of the pixel opening 240OP of the bank layer 240.

The intermediate layer 220 may include the emission layer formed to correspond to the pixel electrode 210. The emission layer may include a high molecular weight organic material or a low molecular weight organic material that emits light of a certain color. In another example, the emission layer may include an inorganic light-emitting material or may include quantum dots.

Although not shown in FIGS. 9 and 10, the intermediate layer 220 may include a first functional layer and a second functional layer respectively disposed under and over the emission layer. For example, the first functional layer may include a hole transport layer (HTL), or may include a hole transport layer and a hole injection layer (HIL). The second functional layer that is an element disposed on the emission layer may include an electron transport layer (ETL) and/or an electron injection layer (EIL). The first functional layer and/or the second functional layer may be a common layer covering (e.g., entirely covering) the substrate 100, like the common electrode 230 described below.

The common electrode 230 may be disposed on the pixel electrode 210 and may overlap the pixel electrode 210. The common electrode 230 may be formed of a conductive material having a low work function. For example, the common electrode 230 may include a transparent layer or a semi-transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another example, the common electrode 230 may further include a layer formed of ITO, IZO, ZnO, or In₂O₃ on the transparent layer or a semi-transparent layer including the above material. The common electrode 230 may be integrally formed to cover (e.g., entirely cover) the substrate 100.

The encapsulation layer 300 may be disposed on the display element layer DEL and may cover the display element layer DEL. The encapsulation layer 300 may include at least one inorganic encapsulation layer and at least one organic encapsulation layer. According to an embodiment, in FIGS. 8 to 10, the encapsulation layer 300 may include a first inorganic encapsulation layer 310, an organic encapsulation layer 320, and a second inorganic encapsulation layer 330 which are sequentially stacked.

Each of the first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

For example, a touch sensor layer may be disposed on the encapsulation layer 300, and an optical functional layer may be disposed on the touch sensor layer. The touch sensor layer may obtain coordinate information according to an external input, for example, a touch event. The optical functional layer may reduce a reflectance of light (or external light) incident on the display apparatus, and/or improve color purity of light emitted from the display apparatus. In an embodiment, the optical functional layer may include a phase retarder and/or a polarizer. The phase retarder may be a film-type phase retarder or a liquid crystal coating-type phase retarder, and may include a λ/2 phase retarder and/or a λ/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in a certain arrangement. The phase retarder and the polarizer may further include a protective film.

An adhesive member may be disposed between the touch sensor layer and the optical functional layer. The adhesive member may be a general member well known in the art without limitation. The adhesive member may be a pressure sensitive adhesive (PSA).

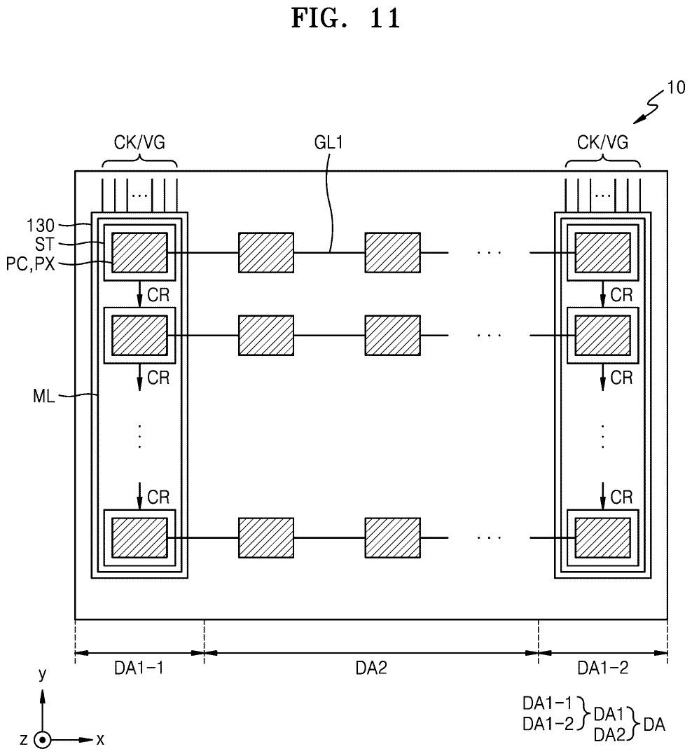

FIG. 11 is a schematic plan view illustrating the display apparatus 10, according to an embodiment.

FIG. 11 illustrates the display area DA of the display apparatus 10 of FIG. 1.

As described above, the display area DA may include the first display area DA1 and the second display area DA2. For example, the first display area DA1 may include the 1-1 display area DA1-1 and the 1-2 display area DA1-2. For example, the first display area DA1 and the second display area DA2 may be arranged along a first direction (e.g., an x-axis direction).

The gate driving circuit 130 may be disposed in the first display area DA1. For example, the gate driving circuit 130 may be disposed in each of the 1-1 display area DA1-1 and the 1-2 display area DA1-2. The gate driving circuit 130 may include stages ST. For example, the stages ST may be arranged along a second direction (e.g., a y-axis direction). The second direction (e.g., the y-axis direction) may intersect the first direction (e.g., the x-axis direction). The gate driving circuit 130 may include the stages ST, and each of the stages ST may receive at least one clock signal CK and at least one voltage signal VG. The stage ST may output a carry signal CR to a front stage ST and/or a rear stage ST.

Pixel circuits PC may be disposed in each of the first display area DA1 and the second display area DA2. For example, the pixel circuits PC may be disposed in each of the 1-1 display area DA1-1, the 1-2 display area DA1-2, and the second display area DA2.

The pixel circuits PC disposed in the first display area DA1 may be arranged along the second direction (e.g., the y-axis direction) to correspond to the stages ST. One stage (or single stage) ST may be connected to one pixel circuit (or single pixel circuit) PC. For example, the first wiring WR1 (see FIG. 9) may electrically connect the pixel circuit PC to the stage ST. Each of the stages ST may output a gate signal GS (see FIG. 3). The gate signal GS (see FIG. 3) output from each of the stages ST may be transmitted to the second gate electrode GE2 (see FIG. 9) of the second transistor T2 (see FIG. 9) of the pixel circuit PC corresponding to the stage ST.

The first gate line GL1 may electrically connect the second gate electrodes GE2 (see FIG. 9) of the second transistors T2 (see FIG. 9) of the pixel circuits PC to each other. The first gate line GL1 may extend in the first direction (e.g., the x-axis direction) to be connected to pixel circuits PC arranged in the same row. The first gate line GL1 may be electrically connected to the second gate electrode GE2 (see FIG. 9) of each of the pixel circuits PC arranged in the same row.

The first gate line GL1 may be disposed on the pixel circuit layer PCL (see FIG. 9). The first gate line GL1 may be disposed on the same layer as the second gate electrode GE2 (see FIG. 9). For example, the first gate line GL1 and the second gate electrode GE2 may be formed as the same layer. For example, the first gate line GL1 may be disposed on the 2-1 gate insulating layer 141 (see FIG. 9). For example, the first gate line GL1, and the second gate electrode GE2 (see FIG. 9) of each of the pixel circuits PC arranged in the same row may be integral with each other.

In a plan view, the metal layer ML and the gate driving circuit 130 may overlap each other. In a plan view, each of the metal layer ML and the gate driving circuit 130 may overlap the first display area DA1. In a plan view, each of the metal layer ML and the gate driving circuit 130 may be spaced apart from the second display area DA2. The gate driving circuit 130 may be provided in plural and may be disposed in each of the 1-1 display area DA1-1 and the 1-2 display area DA1-2. For example, the metal layer ML may be provided in plural and may be disposed in each of the 1-1 display area DA1-1 and the 1-2 display area DA1-2. In a plan view, at least one of the pixel circuits PC may be spaced apart from the gate driving circuit 130. For example, in a plan view, the pixel circuits PC disposed in the second display area DA2 may be spaced apart from the gate driving circuit 130. However, in a plan view, the pixel circuits PC disposed in the first display area DA1 may overlap the gate driving circuit 130.

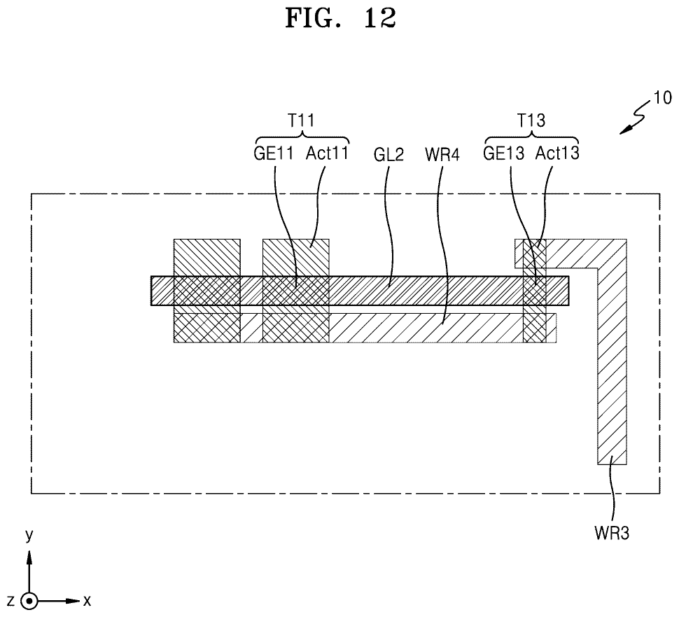

FIGS. 12 to 16 are schematic plan views illustrating the display apparatus 10, according to an embodiment.

FIGS. 12 to 16 illustrate the display area DA of the display apparatus 10 of FIG. 1.

Referring to FIGS. 12 to 16, a method of manufacturing the display apparatus 10 is described.

Referring to FIG. 12, an 11^{th} semiconductor layer Act11 and a 13^{th} semiconductor layer Act13 may be disposed. A second gate line GL2 may be disposed on the 11^{th} semiconductor layer Act11 and the 13^{th} semiconductor layer Act13. A portion of the second gate line GL2 overlapping the 11^{th} semiconductor layer Act11 may form an 11^{th} gate electrode GE11. A portion of the second gate line GL2 overlapping the 13^{th} semiconductor layer Act13 may form an 13^{th} gate electrode GE13. The 11^{th} semiconductor layer Act11 and the 11^{th} gate electrode GE11 may constitute the 11^{th} transistor T11. The 13^{th} semiconductor layer Act13 and the 13^{th} gate electrode GE13 may constitute the 13^{th} transistor T13.

The third wiring WR3 may be electrically connected to the 13^{th} transistor T13 and may transmit a carry signal CR (see FIG. 4) to the 13^{th} transistor T13. For example, the third wiring WR3 may be electrically connected to the 13^{th} semiconductor layer Act13 of the 13^{th} transistor T13.

A fourth wiring WR4 may electrically connect the 11^{th} transistor T11 to the 13^{th} transistor T13. For example, the fourth wiring WR4 may electrically connect the 11^{th} semiconductor layer Act11 of the 11^{th} transistor T11 to the 13^{th} semiconductor layer Act13 of the 13^{th} transistor T13.

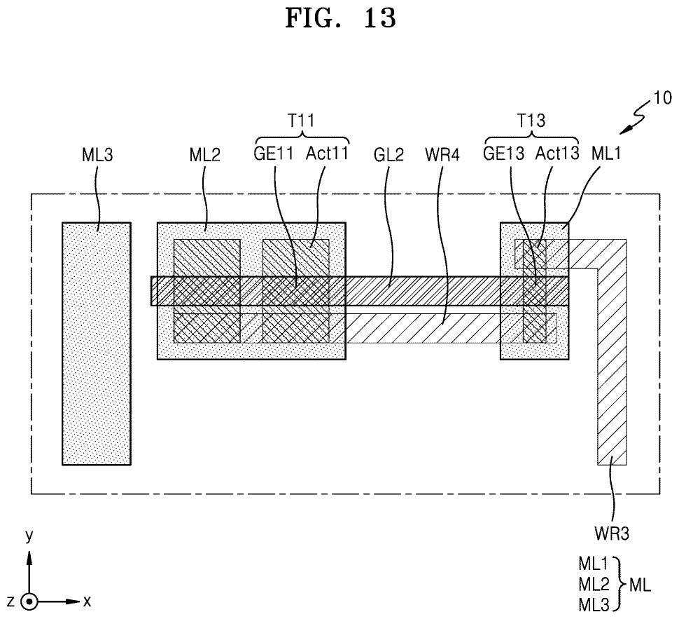

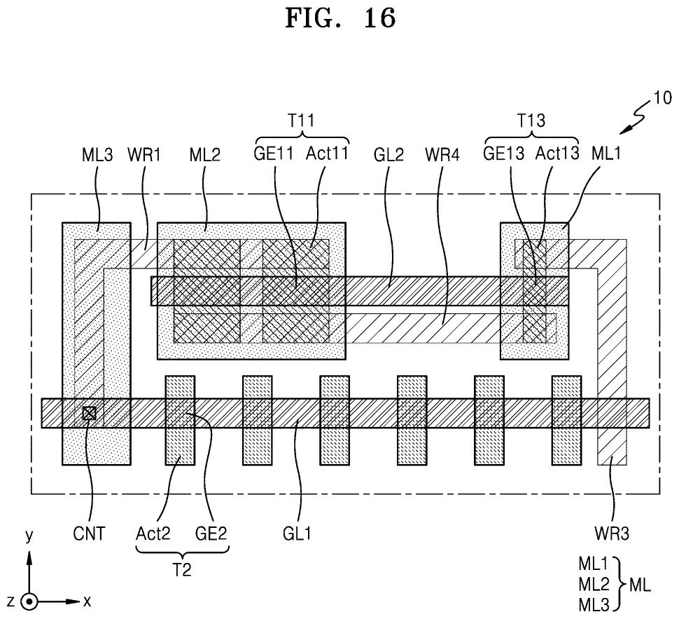

Referring to FIG. 13, the metal layer ML may be disposed on the 11^{th} transistor T11 and the 13^{th} transistor T13. For example, the metal layer ML may include a first metal layer ML1, a second metal layer ML2, and a third metal layer ML3. The first metal layer ML1 may overlap the 13^{th} transistor T13, the second metal layer ML2 may overlap the 11^{th} transistor T11, and the third metal layer ML3 may overlap the first wiring WR1 described below with reference to FIG. 16.

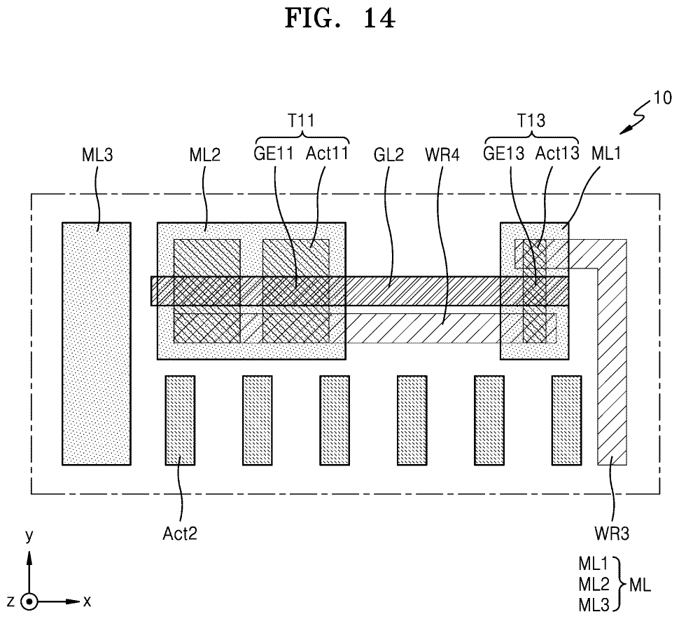

Referring to FIG. 14, second semiconductor layers Act2 may be disposed on the metal layer ML. Although six semiconductor layers Act2 are illustrated in FIG. 14, this is only an example, and the number of second semiconductor layers Act2 is not limited thereto.

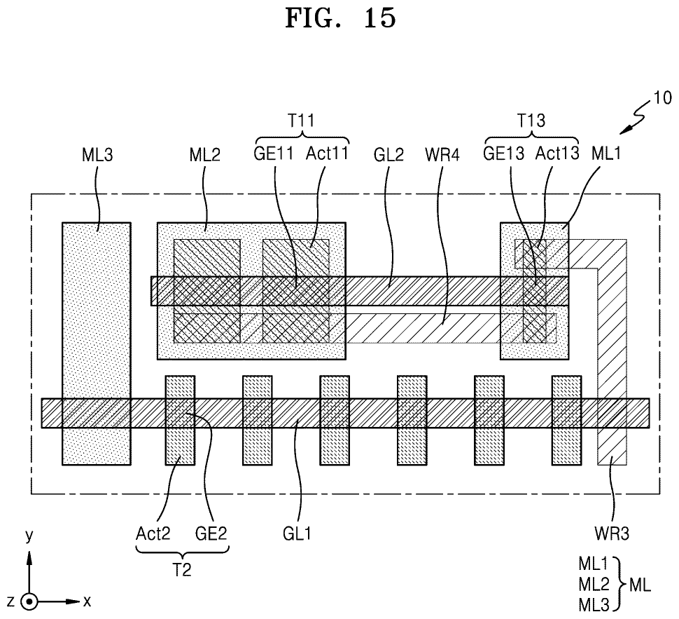

Referring to FIG. 15, the first gate line GL1 may be disposed on the second semiconductor layers Act2. The first gate line GL1 may cross the second semiconductor layers Act2. A portion of the first gate line GL1 overlapping the second semiconductor layer Act2 may form the second gate electrode GE2. The second semiconductor layer Act2 and the second gate electrode GE2 may constitute the second transistor T2.

Referring to FIG. 16, the first wiring WR1 may connect the 11^{th} transistor T11 to the second transistor T2. For example, the first wiring WR1 may be electrically connected to the 11^{th} semiconductor layer Act11 of the 11^{th} transistor T11. For example, the first wiring WR1 may be electrically connected to the first gate line GL1 through a contact hole CNT.

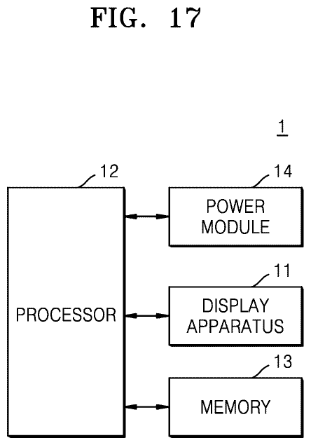

FIG. 17 is a block diagram of an electronic device.

Referring to FIG. 17, the electronic apparatus 1 may comprise the display apparatus 11, a processor 12, a memory 13, and a power module 14. The display apparatus 11 may comprise the display part 10 above mentioned.

The processor 12 may comprise at least one of a central processing unit (CPU), an application processor (AP), a graphic processing unit (GPU), a communication processor (CP), an image signal processor (ISP), and a controller.

Data for operations of the processor 12 or the display apparatus 11 may be stored in the memory 13. When the processor 12 executes an application stored in the memory 13, image data signals and/or input control signals may be transferred to the display apparatus 11, and the display apparatus 11 may process the received signals to output image information through a display screen.

The power module 14 may comprise a power supply module such as a power adapter or a battery device, and a power conversion module that converts power supplied by the power supply module to generate power necessary for operation of the electronic apparatus 1.

At least one of the components of the display apparatus 11 described above may be comprised in the electronic apparatus 1 to the embodiments described above. Additionally, some individual modules functionally comprised in one module may be comprised in the display apparatus while others may be provided separately from the display apparatus.

The display apparatus 11 of FIG. 17 may comprise one of the examples of the display part 10 described in FIGS. 1 to 16. For convenience of description, other descriptions are omitted, but one of ordinary skill in the art can easily and clearly understand the display apparatus 11 of FIG. 17 comprising display part 10 based on the descriptions of FIGS. 1 to 16.

In an embodiment, the electronic apparatus 1 may comprise the memory 13 which stores data information, the processor 12 which generates data signals and/or control signals based on the data information, and the display apparatus 11 that operates based on the data signals and/or control signals.

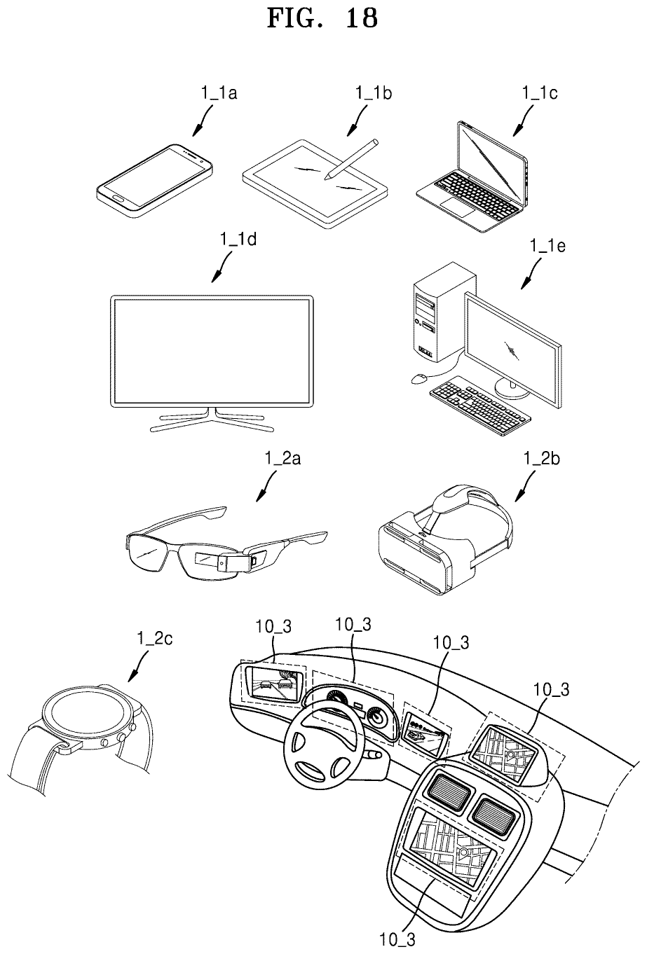

FIG. 18 shows schematic views of various electronic apparatuses.

Referring to FIG. 18, the electronic apparatus 1 may comprise not only electronic devices for displaying image such as smartphone 1_1a, tablet PC 1_1b, laptop 1_1c, TV 1_1d, and desktop monitor 1_1e, but also wearable electronic devices comprising display modules such as smart glass 1_2a, head-mounted display 1_2b, and smart watch 1_2c, as well as vehicle electronic device 10_3 comprising display module such as instrument panel, center fascia, dashboard equipped with Center Information Display, and rearview mirror display of automobile. In an embodiment, a pixel with a reduced change in brightness of a light-emitting element caused by a current leakage phenomenon, and a display apparatus including the pixel may be implemented. However, the scope of the disclosure is not limited by this effect. According to embodiments, in case that a dead area of a display area is reduced, visibility may be improved and durability may increase.

Effects of the disclosure are not limited thereto, and other unmentioned effects will be clearly understood by one of ordinary skill in the art from the appended claims.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus including a display area and a peripheral area, the display apparatus comprising:
a substrate;
a first layer disposed on the substrate and comprising a gate driving circuit comprising a first transistor;
a second layer disposed on the first layer and comprising a metal layer; and
a pixel circuit layer disposed on the second layer and comprising a plurality of pixel circuits each comprising a second transistor,
wherein, in a plan view, the metal layer and the gate driving circuit overlap each other.

2. The display apparatus of claim 1, wherein
the display area comprises a first display area and a second display area,
in a plan view, each of the metal layer and the gate driving circuit overlaps the first display area, and
in a plan view, each of the metal layer and the gate driving circuit is spaced apart from the second display area.

3. The display apparatus of claim 2, wherein
the first display area comprises a 1-1 display area and a 1-2 display area, and
the gate driving circuit is provided in plural and is disposed in each of the 1-1 display area and the 1-2 display area.

4. The display apparatus of claim 3, wherein the second display area is disposed between the 1-1 display area and the 1-2 display area.

5. The display apparatus of claim 1, further comprising:
a first wiring that electrically connects a first semiconductor layer of the first transistor to a second gate electrode of the second transistor.

6. The display apparatus of claim 5, wherein the first wiring passes through the second layer.

7. The display apparatus of claim 1, wherein the metal layer has a substantially constant voltage level.

8. The display apparatus of claim 7, further comprising:
a second wiring that electrically connects the metal layer to a driving voltage.

9. The display apparatus of claim 1, further comprising:
a first gate line that electrically connects second gate electrodes of the second transistors of the plurality of pixel circuits to each other.

10. The display apparatus of claim 9, wherein the first gate line is disposed on the pixel circuit layer.

11. A display apparatus including a display area and a peripheral area, the display apparatus comprising:
a substrate;
a first layer disposed on the substrate and comprising a gate driving circuit comprising a first transistor;
a second layer disposed on the first layer and comprising a metal layer overlapping the gate driving circuit; and
a pixel circuit layer disposed on the second layer and comprising a plurality of pixel circuits each comprising a second transistor,
wherein, in a plan view, at least one of the plurality of pixel circuits is spaced apart from the gate driving circuit.

12. The display apparatus of claim 11, wherein
the display area comprises a first display area and a second display area,
in a plan view, each of the metal layer and the gate driving circuit overlaps the first display area, and
each of the metal layer and the gate driving circuit is spaced apart from the second display area.

13. The display apparatus of claim 12, wherein
the first display area comprises a 1-1 display area and a 1-2 display area, and
the gate driving circuit is provided in plural and is disposed in each of the 1-1 display area and the 1-2 display area.

14. The display apparatus of claim 13, wherein the second display area is disposed between the 1-1 display area and the 1-2 display area.

15. The display apparatus of claim 11, further comprising:
a first wiring that electrically connects a first semiconductor layer of the first transistor to a second gate electrode of the second transistor.

16. The display apparatus of claim 15, wherein the first wiring passes through the second layer.

17. The display apparatus of claim 11, wherein the metal layer has a substantially constant voltage level.

18. The display apparatus of claim 17, further comprising:
a second wiring that electrically connects the metal layer to a driving voltage.

19. The display apparatus of claim 11, further comprising:
a first gate line that electrically connects second gate electrodes of the second transistor of the plurality of pixel circuits to each other.

20. An electronic device comprising:
a display apparatus comprising a display area and a peripheral area, the display apparatus comprising:
a substrate;
a first layer disposed on the substrate and comprising a gate driving circuit comprising a first transistor,
a second layer disposed on the first layer and comprising a metal layer; and
a pixel circuit layer disposed on the second layer and comprising a plurality of pixel circuits each comprising a second transistor,
wherein, in a plan view, the metal layer and the gate driving circuit overlap each other.
